(19) United States
(12) Patent Application Publication
(10) Pub. No.: US 2024/0349476 A1
(43) Pub. Date: Oct. 17, 2024

(54) SEMICONDUCTOR DEVICE AND METHOD OF FABRICATING THE SAME

(71) Applicant: SAMSUNG ELECTRONICS CO., LTD., Suwon-si (KR)

(72) Inventors: SUBIN LEE, Suwon-si (KR); HYOKYEOM KIM, Suwon-si (KR); JAE HYUN KANG, Suwon-si (KR); JONGWON SEO, Suwon-si (KR)

(73) Assignee: SAMSUNG ELECTRONICS CO., LTD., Suwon-si (KR)

(21) Appl. No.: 18/529,551

(22) Filed: Dec. 5, 2023

(30) Foreign Application Priority Data
Apr. 17, 2023 (KR) 10-2023-0050171

(51) Int. Cl. H10B 10/00

(52) U.S. Cl. CPC H10B 10/18

(57) ABSTRACT

A semiconductor device is provided. The semiconductor device includes: a substrate including first and second active regions wherein a boundary is provided between the first and second active regions, a device isolation layer on the substrate in a trench between the first and second active regions, a first channel pattern and a first source/drain pattern on the first active region, a second channel pattern and a second source/drain pattern on the second active region, a first gate electrode on the first channel pattern and extending across the first active regions, a second gate electrode on the second channel pattern and extending across the second active regions, and active contacts on the first and second source/drain patterns. The device isolation layer includes a protrusion structure between the first active regions. The protrusion structure is adjacent to the boundary.

### CROSS-REFERENCE TO RELATED APPLICATION

This application claims priority to Korean Patent Application No. 10-2023-0050171, filed on Apr. 17, 2023, in the Korean Intellectual Property Office, the disclosure of which is incorporated by reference herein in its entirety.

### BACKGROUND

The present disclosure relates to a semiconductor device and a method of fabricating the same, and more particularly, to a semiconductor device including a field effect transistor and a method of fabricating the same.

A semiconductor device includes an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device. Accordingly, various studies have been conducted to develop methods of fabricating semiconductor devices having a small scale without deteriorated operating characteristics.

### SUMMARY

Some embodiments provide a semiconductor device having increased reliability and improved electrical properties.

Some embodiments provide a method of fabricating a semiconductor device having increased reliability and improved electrical properties.

According to an aspect of an embodiment, a semiconductor device includes: a substrate that includes first active regions and second active regions, wherein the first active regions are arranged along a first direction, wherein the second active regions are arranged along the first direction, and wherein a boundary between the first active regions and the second active regions extends in the first direction; a device isolation layer on the substrate in a trench between the first active regions and the second active regions; a first channel pattern and a first source/drain pattern on each of the first active regions; a second channel pattern and a second source/drain pattern on each of the second active regions; a first gate electrode on the first channel pattern, wherein the first gate electrode extends in the first direction across the first active regions; a second gate electrode on the second channel pattern, wherein the second gate electrode extends in the first direction across the second active regions; and a plurality of active contacts on the first source/drain pattern on each of the first active regions and the second source/drain pattern on each of the second active regions. The device isolation layer includes a protrusion structure between adjacent ones of the first active regions. The protrusion structure is adjacent to the boundary.

According to an aspect of an embodiment, a semiconductor device includes: a substrate that includes a first active region and a second active region, wherein the first active region and the second active region are adjacent to each other along a first direction and have a common conductivity type; a device isolation layer in a trench between the first active region and the second active region; a first source/drain pattern on the first active region; a second source/drain pattern on the second active region; a liner layer on the device isolation layer and the first and second source/drain patterns; an interlayer dielectric layer on the liner layer; a first active contact that extends into the interlayer dielectric layer and is coupled to the first source/drain pattern; and a second active contact that extends into the interlayer dielectric layer and is coupled to the second source/drain pattern. The device isolation layer includes a protrusion structure that extends vertically between the first source/drain pattern and the second source/drain pattern. The protrusion structure has a planar top surface.

According to an aspect of an embodiment, a semiconductor device includes: a substrate that includes first active regions and second active regions, wherein the first active regions are adjacent to each other along a first direction, and wherein the second active regions are adjacent to each other along the first direction; a device isolation layer in a first trench between the first active regions and a second trench between the second active regions; a first channel pattern and a first source/drain pattern on each of the first active regions; a second channel pattern and a second source/drain pattern on each of the second active regions, wherein a conductivity type of the second source/drain pattern is different from a conductivity type of the first source/drain pattern; a first gate electrode on the first channel pattern, wherein the first gate electrode extends in the first direction across the first active regions; a first gate dielectric layer between the first gate electrode and the first channel pattern; a second gate electrode on the second channel pattern, wherein the second gate electrode extends in the first direction across the second active regions; a second gate dielectric layer between the second gate electrode and the second channel pattern; a first active contact on the first source/drain pattern; a second active contact on the second source/drain pattern; a first gate contact on the first gate electrode; a second gate contact on the second gate electrode; and a first metal layer electrically connected to the first gate contact, the second gate contact, the first active contact and the second active contact. The device isolation layer between adjacent ones of the first active regions includes a protrusion structure. A recessed top surface is formed in the device isolation layer between adjacent ones of the second active regions.

### BRIEF DESCRIPTION OF DRAWINGS

The above and other aspects and features will be more apparent from the following description of embodiments taken in conjunction with the accompanying drawings, in which:

FIG. 1 illustrates a plan view showing a semiconductor device according to some embodiments.

FIG. 2 illustrates a plan view of a peripheral region depicted in FIG. 1, showing a semiconductor device according to some embodiments.

FIGS. 3A, 3B, 3C, 3D, and 3E illustrate cross-sectional views respectively taken along lines A-A′, B-B′, C-C′, D-D′, and E-E′ of FIG. 2.

FIGS. 4, 6, 8, and 10 illustrate plan views showing a method of fabricating a semiconductor device according to some embodiments.

FIGS. 5A, 7A, 9A, and 11A illustrate cross-sectional views taken along line A-A′ of FIGS. 4, 6, 8, and 10, respectively.

FIGS. 5B, 7B, 9B, and 11B illustrate cross-sectional views taken along line B-B′ of FIGS. 4, 6, 8, and 10, respectively.

FIG. 11C illustrates a cross-sectional view taken along line C-C′ of FIG. 10.

FIG. 12 illustrates a plan view showing a method of fabricating a semiconductor device according to a comparative example.

FIG. 13 illustrates a cross-sectional view taken along line A-A′ of FIG. 12.

FIGS. 14A, 14B, and 14C illustrate cross-sectional views respectively taken along lines A-A′, B-B′, and C-C′ of FIG. 2, showing a semiconductor device according to some embodiments.

FIG. 15 illustrates a cross-sectional view taken along line B-B′ of FIG. 2, showing a semiconductor device according to some embodiments.

### DETAILED DESCRIPTION

Embodiments will be described with reference to the accompanying drawings. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation.

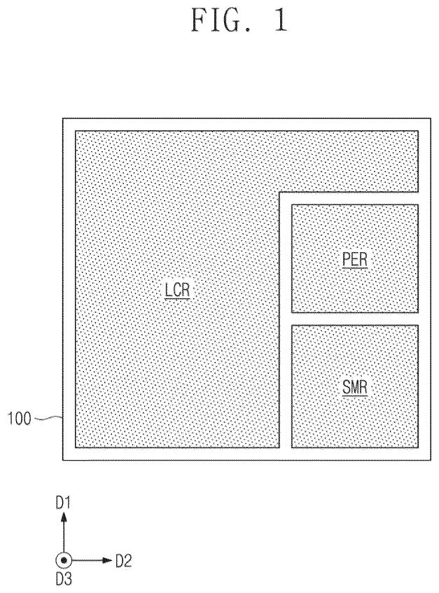

FIG. 1 illustrates a plan view showing a semiconductor device according to some embodiments. Referring to FIG. 1, a logic chip may be provided as a semiconductor device according to an embodiment. The semiconductor device may include a logic cell region LCR, a memory cell region SMR, and a peripheral region PER on a substrate 100. The substrate 100 may be a compound semiconductor substrate or a semiconductor substrate including silicon, germanium, or silicon-germanium. For example, the substrate 100 may be a silicon substrate.

The logic cell region LCR may include a logic cell that means a logic device, such as AND, OR, XOR, XNOR, or inverter, that performs a specific function. The logic cell on the logic cell region LCR may include CMOS transistors for constituting a logic device and wiring lines through which the transistors are connected to each other.

The memory cell region SMR may include a static random access memory (SRAM) cell. The SRAM cell may include a plurality of memory transistors. For example, the SRAM cell may include a first pull-up transistor, a first pull-down transistor, a second pull-up transistor, a second pull-down transistor, a first pass-gate transistor, and a second pass-gate transistor.

The peripheral region PER may be a core/peripheral region of the memory cell region SMR. The peripheral region PER may include a long-gate transistor (or a long-channel transistor) whose gate length (or channel length) is relatively high and a short-gate transistor (or a short-channel transistor) whose gate length (or channel length) is relatively small.

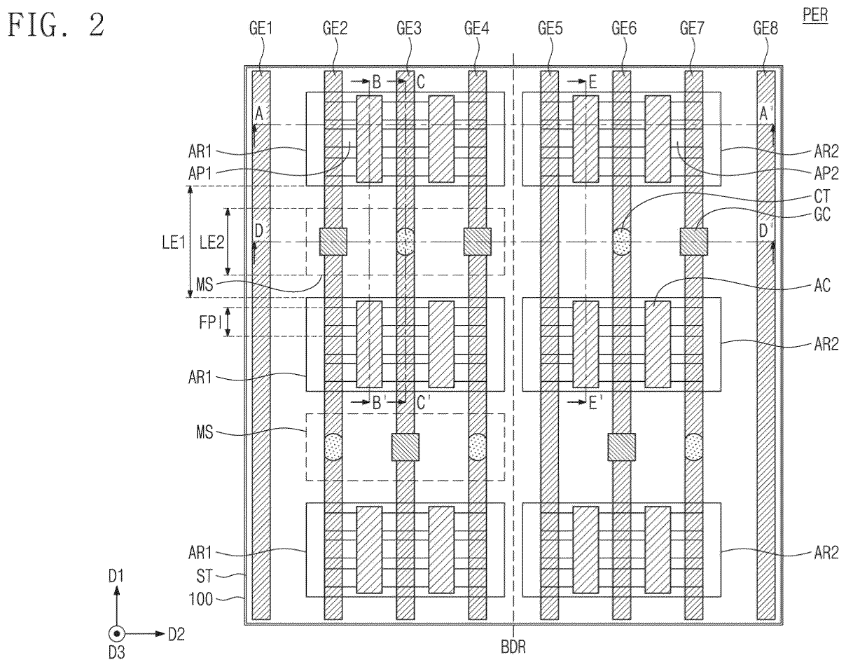

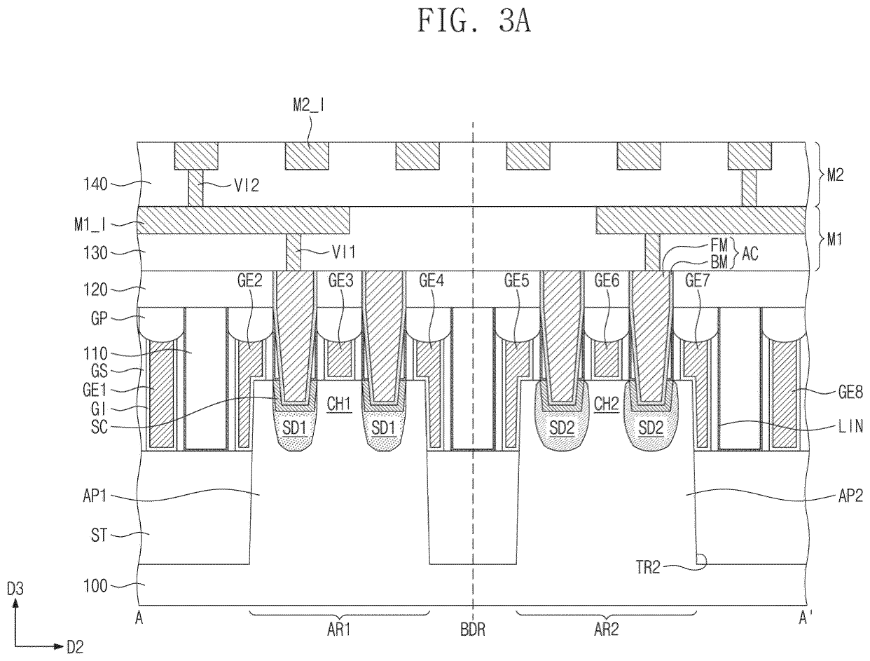

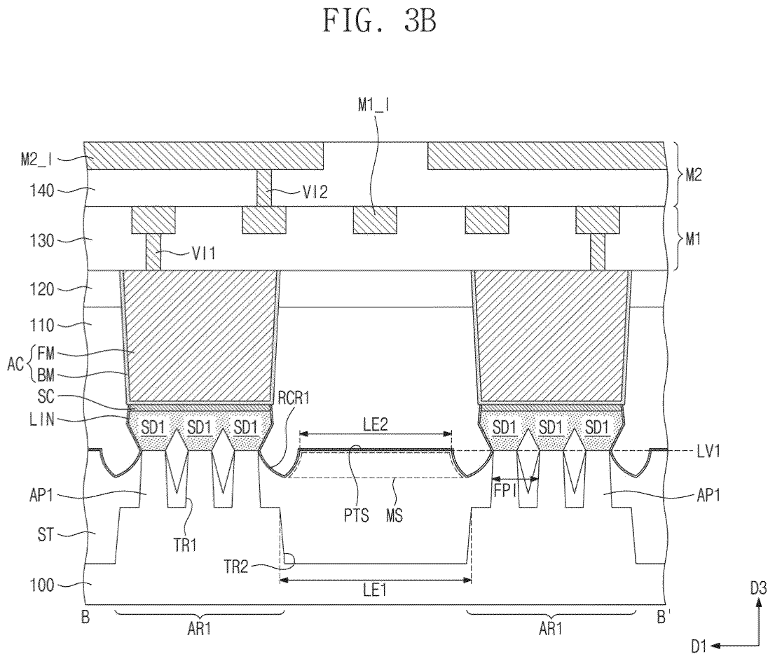

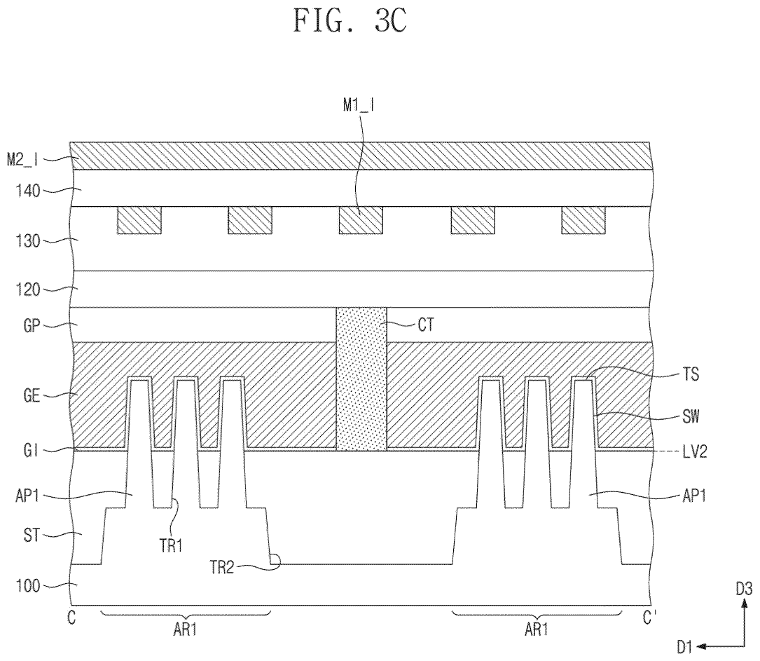

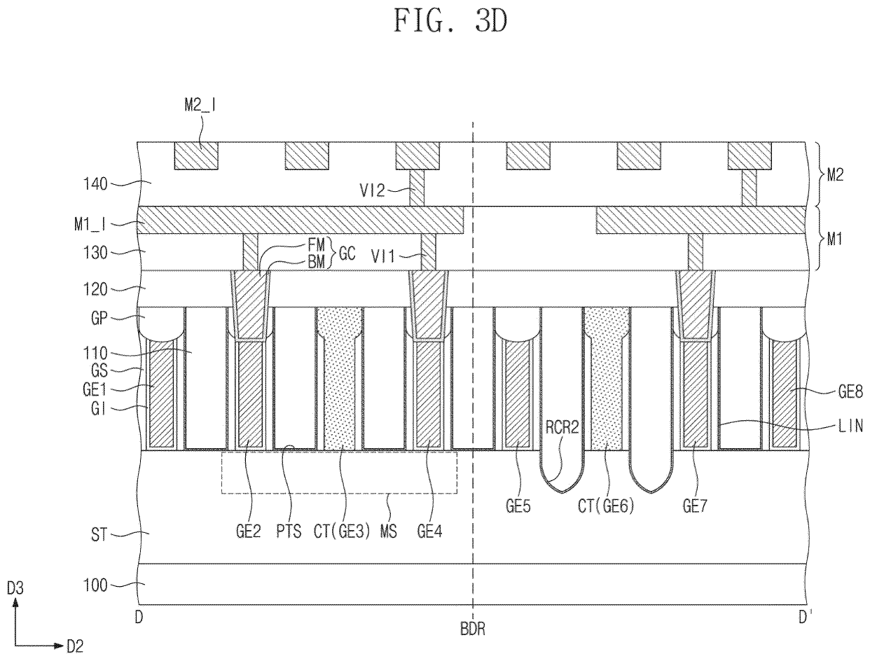

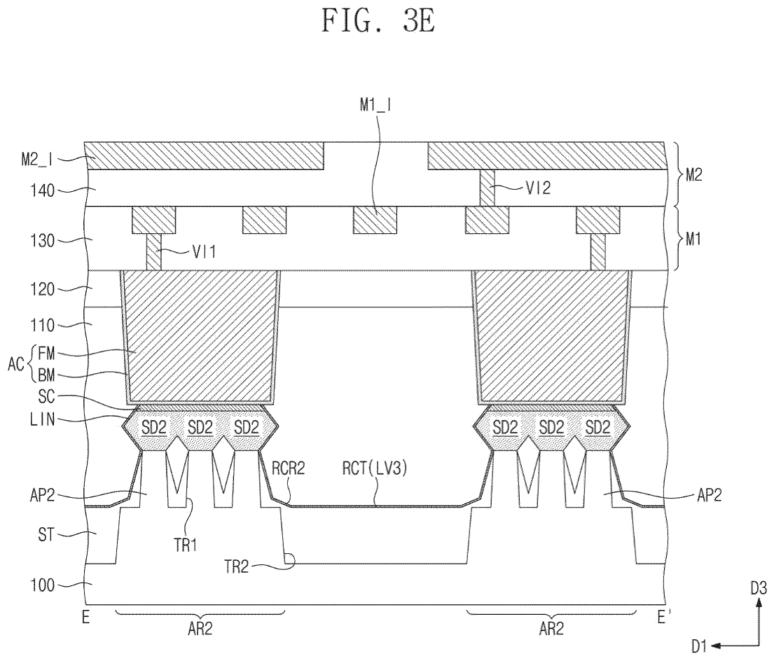

FIG. 2 illustrates a plan view of the peripheral region PER depicted in FIG. 1, showing a semiconductor device according to some embodiments. FIGS. 3A, 3B, 3C, 3D, and 3E illustrate cross-sectional views respectively taken along lines A-A′, B-B′, C-C′, D-D′, and E-E′ of FIG. 2.

Referring to FIGS. 2 and 3A to 3E, an example of the peripheral region PER of the logic chip depicted in FIG. 1 is illustrated. In an embodiment, the peripheral region PER depicted in FIGS. 2 and 3A to 3E may include a short-channel transistor.

The peripheral region PER may include first active regions AR1 and second active regions AR2. The first and second active regions AR1 and AR2 may be defined by a second trench TR2 formed on an upper portion of the substrate 100. The first active regions AR1 may be arranged along a first direction D1. The second active regions AR2 may be arranged along the first direction D1. The first active regions AR1 may be adjacent in a second direction D2 to the second active regions AR2.

Each of the first active regions AR1 may be one of an n-type metal-oxide-semiconductor field-effect transistor (NMOSFET) region and a p-type metal-oxide-semiconductor field-effect transistor (PMOSFET) region, and each of the second active regions AR2 may be another of an NMOSFET region and a PMOSFET region. For example, each of the first active regions AR1 may be an NMOSFET region, and each of the second active regions AR2 may be a PMOSFET region.

At least one first active pattern AP1 may be provided on each of the first active regions AR1. At least one second active pattern AP2 may be provided on each of the second active regions AR2. Each of the first and second active patterns AP1 and AP2 may have a linear or bar shape that extends in the second direction D2. The first and second active patterns AP1 and AP2 may be vertically protruding portions of the substrate 100.

A first trench TR1 may be defined between neighboring first active patterns AP1 (see FIG. 3B). A first trench TR1 may be formed between neighboring second active patterns AP2 (see FIG. 3E). The first trench TR1 may be shallower than the second trench TR2.

A device isolation layer ST may fill the first and second trenches TR1 and TR2. The device isolation layer ST may include a silicon oxide layer. The first and second active patterns AP1 and AP2 may have upper portions that vertically protrude upwards from the device isolation layer ST (see FIGS. 3C and 3E). The first and second active patterns AP1 and AP2 may each have a fin shape at the upper portion thereof. For example, the first and second active patterns AP1 and AP2 may each be an active fin. The device isolation layer ST may cover neither the upper portion of the first active pattern AP1 nor the upper portion of the second active pattern AP2. The device isolation layer ST may cover a lower sidewall of each of the first and second active patterns AP1 and AP2.

First source/drain patterns SD1 may be provided on the first active region AR1. The first source/drain patterns SD1 may be provided on the upper portions of the first active patterns AP1. The first source/drain patterns SD1 may be impurity regions of a first conductivity type (e.g., n-type). A first channel pattern CH1 may be interposed between a pair of first source/drain patterns SD1 that are adjacent to each other in the second direction D2.

Second source/drain patterns SD2 may be provided on the second active region AR2. The second source/drain patterns SD2 may be provided on the upper portions of the second active patterns AP2. The second source/drain patterns SD2 may be impurity regions of a second conductivity type (e.g., p-type). A second channel pattern CH2 may be interposed between a pair of second source/drain patterns SD2 that are adjacent to each other in the second direction D2.

The first and second source/drain patterns SD1 and SD2 may be epitaxial patterns formed by a selective epitaxial growth process. For example, the first and second source/drain patterns SD1 and SD2 may have top surfaces that are coplanar with those of the first and second channel patterns CH1 and CH2. For another example, the first and second source/drain patterns SD1 and SD2 may have top surfaces that are higher than those of the first and second channel patterns CH1 and CH2.

For example, the first source/drain patterns SD1 may include the same semiconductor element (e.g., Si) as that of the substrate 100. The second source/drain patterns SD2 may include a semiconductor element (e.g., SiGe) whose lattice constant is greater than that of a semiconductor element of the substrate 100. A pair of second source/drain patterns SD2 may provide a compressive stress to the second channel pattern CH2 therebetween.

Gate electrodes GE may be provided to extend in the first direction D1, while running across the first and second active patterns AP1 and AP2. The gate electrodes GE may be arranged at a first pitch along the second direction D2. For example, the gate electrodes GE may include first to eighth gate electrodes GE1 to GE8 that are sequentially arranged along the second direction D2.

The gate electrode GE may vertically overlap the channel pattern CH1 or CH2. Referring back to FIG. 3C, the gate electrode GE may be provided on a top surface TS and opposite sidewalls SW1 of the channel pattern CH1 or CH2. For example, a transistor according to the present embodiment may be a three-dimensional field effect transistor (e.g., FinFET) in which the gate electrode GE three-dimensionally surrounds the channel pattern CH1 or CH2.

Referring back to FIGS. 2 and 3A to 3E, a gate cutting pattern CT may be provided to penetrate (i.e., extend into) the gate electrode GE. The gate cutting pattern CT may be disposed to overlap the gate electrode GE. The gate cutting pattern CT may extend in a third direction D3 from the device isolation layer ST to a second interlayer dielectric layer 120 which will be discussed below. The gate cutting pattern CT may divide the gate electrode GE into two gate electrodes GE. For example, the gate cutting pattern CT may include a silicon-based dielectric material, such as a silicon nitride layer, a silicon oxide layer, or a combination thereof.

A pair of gate spacers GS may be disposed on opposite sidewalls of each of the gate electrodes GE. The gate spacers GS may extend in the first direction D1 along the gate electrode GE. The gate spacer GS may have a top surface higher than that of the gate electrode GE. The top surface of the gate spacer GS may be lower than that of a gate capping pattern GP which will be discussed below. The top surface of the gate spacer GS may be lower than that of the gate cutting pattern CT. The gate spacer GS may include at least one selected from SiCN, SiCON, and SiN.

A gate capping pattern GP may be provided on each of the gate electrodes GE. The gate capping pattern GP may extend in the first direction D1 along the gate electrode GE. The gate capping pattern GP may include a material having an etch selectivity with respect to first and second interlayer dielectric layers 110 and 120 which will be discussed below. For example, the gate capping pattern GP may include at least one selected from SiON, SiCN, SiCON, and SiN.

A gate dielectric layer GI may be interposed between the gate electrode GE and the first channel pattern CH1 and between the gate electrode GE and the second channel pattern CH2. The gate dielectric layer GI may extend along a bottom surface of the gate electrode GE that overlies the gate dielectric layer GI. For example, the gate dielectric layer GI may directly cover the top surface TS and the sidewall SW of the channel pattern CH1 or CH2. The gate dielectric layer GI may cover a top surface of the device isolation layer ST that underlies the gate electrode GE (see FIG. 3C).

In an embodiment, the gate dielectric layer GI may include a silicon oxide layer and a high-k dielectric layer. The high-k dielectric layer may include a high-k dielectric material whose dielectric constant is greater than that of a silicon oxide layer. For example, the high-k dielectric material may include at least one selected from hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

Alternatively, a semiconductor device according to an embodiment may include a negative capacitance (NC) field effect transistor (FET) that uses a negative capacitor. For example, the gate dielectric layer GI may include a ferroelectric material layer that exhibits ferroelectric properties and a paraelectric material layer that exhibits paraelectric properties.

The ferroelectric material layer may have a negative capacitance, and the paraelectric material layer may have a positive capacitance. For example, when two or more capacitors are connected in series, and when each capacitor has a positive capacitance, an overall capacitance may be reduced to be less than the capacitance of each capacitor. In contrast, when at least one of two or more capacitors connected in series has a negative capacitance, an overall capacitance may have a positive value that is increased to be greater than an absolute value of the capacitance of each capacitor.

When the ferroelectric material layer having a negative capacitance is connected in series to the paraelectric material layer having a positive capacitance, there may be an increase in overall capacitance of the ferroelectric and paraelectric material layers that are connected in series. The increase in overall capacitance may be used to allow a transistor including the ferroelectric material layer to have a sub-threshold swing (SS) of less than about 60 mV/decade at room temperature (i.e., approximately 65 to approximately 80 degrees Fahrenheit).

The ferroelectric material layer may have ferroelectric properties. The ferroelectric material layer may include, for example, one or more of hafnium oxide, hafnium zirconium oxide, barium strontium titanium oxide, and lead zirconium titanium oxide. For example, the hafnium zirconium oxide may be a material in which hafnium oxide is doped with zirconium (Zr). For another example, the hafnium zirconium oxide may be a compound of hafnium (Hf), zirconium (Zr), and oxygen (O).

The ferroelectric material layer may further include impurities doped therein. For example, the impurities may include at least one selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of impurities included in the ferroelectric material layer may be changed depending on what ferroelectric material is included in the ferroelectric material layer.

When the ferroelectric material layer includes hafnium oxide, the ferroelectric material layer may include at least one of impurities such as gadolinium (Gd), silicon (Si), zirconium (Zr), aluminum (Al), and yttrium (Y).

When the impurities are aluminum (Al), the ferroelectric material layer may include about 3 to 8 atomic percent aluminum. In this description, the ratio of impurities may be a ratio of aluminum to the sum of hafnium and aluminum.

When the impurities are silicon (Si), the ferroelectric material layer may include about 2 to about 10 atomic percent silicon. When the impurities are yttrium (Y), the ferroelectric material layer may include about 2 to about 10 atomic percent yttrium. When the impurities are gadolinium (Gd), the ferroelectric material layer may include about 1 to 7 atomic percent gadolinium. When the impurities are zirconium (Zr), the ferroelectric material layer may include about 50 to about 80 atomic percent zirconium.

The paraelectric material layer may have paraelectric properties. The paraelectric material layer may include, for example, at least one selected from silicon oxide and high-k metal oxide. The metal oxide included in the paraelectric material layer may include, for example, one or more of hafnium oxide, zirconium oxide, and aluminum oxide, but embodiments are not limited thereto.

The ferroelectric and paraelectric material layers may include the same material. The ferroelectric material layer may have ferroelectric properties, but the paraelectric material layer may not have ferroelectric properties. For example, when the ferroelectric material layer and the paraelectric material layer include hafnium oxide, the hafnium oxide included in the ferroelectric material layer may have a crystal structure different from that of the hafnium oxide included in the paraelectric material layer.

The ferroelectric material layer may have a thickness having ferroelectric properties. The thickness of the ferroelectric material layer may range, for example, from about 0.5 nm to about 10 nm, but embodiments are not limited thereto. Because different ferroelectric materials have different critical thicknesses that exhibit ferroelectric properties, the thickness of the ferroelectric material layer may depend on ferroelectric material.

For example, the gate dielectric layer GI may include a single ferroelectric material layer. For another example, the gate dielectric layer GI may include a plurality of ferroelectric material layers that are spaced apart from each other. The gate dielectric layer GI may have a stack structure in which a plurality of ferroelectric material layers are alternately stacked with a plurality of paraelectric material layers.

The gate electrode GE may include a first metal pattern and a second metal pattern on the first metal pattern. The first metal pattern may be provided on the gate dielectric layer GI and may be adjacent to the channel pattern CH1 or CH2. The first metal pattern may include a work-function metal that controls a threshold voltage of a transistor. A thickness and composition of the first metal pattern may be adjusted to achieve a desired threshold voltage of a transistor.

The first metal pattern may include a metal nitride layer. For example, the first metal pattern may include nitrogen (N) and at least one metal selected from titanium (Ti), tantalum (Ta), aluminum (Al), tungsten (W), and molybdenum (Mo). In addition, the first metal pattern may further include carbon (C). The first metal pattern may include a plurality of stacked work-function metal layers.

The second metal pattern may include metal whose resistance is less than that of the first metal pattern. For example, the second metal pattern may include at least one metal selected from tungsten (W), aluminum (Al), titanium (Ti), and tantalum (Ta).

A liner layer LIN may be provided to cover the device isolation layer ST and the first and second source/drain patterns SD1 and SD2. The liner layer LIN may include one or more of a silicon nitride layer and a silicon oxynitride layer. The liner layer LIN may serve as an etch stop layer for an active contact AC which will be discussed below.

A first interlayer dielectric layer 110 may be provided on the liner layer LIN. The first interlayer dielectric layer 110 may be provided on the gate spacers GS and the first and second source/drain patterns SD1 and SD2. The first interlayer dielectric layer 110 may have a top surface substantially coplanar with those of the gate capping patterns GP. The top surface of the first interlayer dielectric layer 110 may be substantially coplanar with those of the gate cutting patterns CT.

The first interlayer dielectric layer 110 may be provided thereon with a second interlayer dielectric layer 120 that covers the gate capping patterns GP and the gate cutting patterns CT. A third interlayer dielectric layer 130 may be provided on the second interlayer dielectric layer 120. A fourth interlayer dielectric layer 140 may be provided on the third interlayer dielectric layer 130. For example, the first to fourth interlayer dielectric layers 110 to 140 may include a silicon oxide layer.

Active contacts AC may be provided to penetrate the first and second interlayer dielectric layers 110 and 120 to come into electrical connection with the first and second source/drain patterns SD1 and SD2. Each of the active contacts AC may be provided between a pair of gate electrodes GE. When viewed in plan, each of the active contacts AC may have a linear or bar shape that extends in the first direction D1.

The active contact AC may be a self-aligned contact. For example, the gate capping pattern GP and the gate spacer GS may be used to form the active contact AC in a self-alignment manner. The active contact AC may cover, for example, at least a portion of a sidewall of the gate spacer GS. The active contact AC may cover a portion of the top surface of the gate capping pattern GP.

A silicide pattern SC may be interposed between the active contact AC and each of the first and second source/drain patterns SD1 and SD2. The active contact AC may be electrically connected through the silicide pattern SC to one of the first and second source/drain patterns SD1 and SD2. The silicide pattern SC may include metal silicide, for example, at least one selected from titanium silicide, tantalum silicide, tungsten silicide, nickel silicide, and cobalt silicide.

Gate contacts GC may be provided to penetrate the second interlayer dielectric layer 120 and the gate capping pattern GP to come into electrical connection with the gate electrodes GE. Each of the active contact AC and the gate contact GC may include a conductive pattern FM and a barrier pattern BM that surrounds the conductive pattern FM. For example, the conductive pattern FM may include at least one metal selected from aluminum, copper, tungsten, molybdenum, and cobalt. The barrier pattern BM may cover sidewalls and a bottom surface of the conductive pattern FM. The barrier pattern BM may include a metal layer and a metal nitride layer. The metal layer may include at least one selected from titanium, tantalum, tungsten, nickel, cobalt, and platinum. The metal nitride layer may include at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PtN) layer.

A first metal layer M1 may be provided in the third interlayer dielectric layer 130. For example, the first metal layer M1 may include a plurality of first wiring lines M1_I. Each of the first wiring lines M1_I may have a linear shape that extends in the second direction D2. The first wiring lines M1_I of the first metal layer M1 may be arranged at a second pitch along the first direction D1. For example, the second pitch may be less than the first pitch.

The first metal layer M1 may further include first vias VI1. The first vias VI1 may be correspondingly provided below the first wiring lines M1_I of the first metal layer M1. The active contact AC may be electrically connected through the first via VI1 to the first wiring line M1_I. The gate contact GC may be electrically connected through the first via VI1 to the first wiring line M1_I.

In an embodiment, the first wiring line M1_I and its underlying first via VI1 may be formed by individual processes. For example, the first wiring line M1_I and the first via VI1 may each be formed by a single damascene process. A sub-20 nm process may be employed to fabricate a semiconductor device according to the present embodiment.

A second metal layer M2 may be provided in the fourth interlayer dielectric layer 140. The second metal layer M2 may include a plurality of second wiring lines M2_I. Each of the second wiring lines M2_I of the second metal layer M2 may have a linear shape that extends in the first direction D1.

The second metal layer M2 may further include second vias VI2 that are correspondingly provided below the second wiring lines M2_I. The first wiring line M1_I of the first metal layer M1 may be electrically connected through the second via VI2 to the second wiring line M2_I of the second metal layer M2. The second wiring line M2_I and its underlying second via VI2 may be simultaneously formed by a dual damascene process.

The first and second metal layers M1 and M2 may have wiring lines that include the same or different conductive materials. For example, the first and second metal layers M1 and M2 may have wiring lines that include at least one metallic material selected from aluminum, copper, tungsten, molybdenum, and cobalt. Other metal layers (e.g., M3, M4, M5, etc.) may be additionally stacked on the fourth interlayer dielectric layer 140. Each of the stacked metal layers may include wiring lines for routing between cells.

An N/P boundary BDR may extend in the first direction D1 between the first active region AR1 and the second active region AR2. According to an embodiment, at least two first active regions AR1 having the same conductivity type may be arranged along the first direction D1. The first active regions AR1 may be adjacent to the N/P boundary BDR.

The device isolation layer ST between neighboring first active regions AR1 may include a protrusion structure MS provided at an upper portion thereof (see FIG. 3B). The protrusion structure MS may be a upwardly projecting region of the device isolation layer ST. The protrusion structure MS may have a flat top surface PTS. When viewed in plan, the protrusion structure MS may have a bar shape that extends in the second direction D2. The protrusion structure MS may be adjacent to the N/P boundary BDR. The protrusion structure MS may not pass beyond the N/P boundary BDR.

A first recess region RCR1 may be defined between the protrusion structure MS and the first active pattern AP1. The first recess region RCR1 may be a recessed area formed at an upper portion of the device isolation layer ST. The first recess region RCR1 and the protrusion structure MS may be directly covered with the liner layer LIN. In an embodiment, the liner layer LIN may directly cover the flat top surface PTS of the protrusion structure MS (see FIG. 3B).

Referring to FIGS. 2 and 3B, an interval between the first active regions AR1 where the protrusion structure MS is positioned may be a first length LE1 in the first direction D1. A width in the first direction D1 of the protrusion structure MS may be a second length LE2. A pitch between neighboring first active patterns AP1 may be a fin pitch FPI. The second length LE2 may have a minimum size in accordance with a design rule of fabrication process for a second hardmask layer MAP2 which will be discussed below. The first length LE1 may be at least a sum of twice the fin pitch FPI and the second length LE2 (LE1=2×FPI+LE2). For example, the second length LE2 may have a value the same as or less than that obtained by subtracting twice the fin pitch FPI from the first length LE1.

In an embodiment, the second to fourth gate electrodes GE2 to GE4 may run across the first active regions AR1. The second to fourth gate electrodes GE2 to GE4 may also run across the protrusion structure MS (see FIG. 3D). The fifth to seventh gate electrodes GE5 to GE7 may run across the second active regions AR2. A second recess region RCR2 may be defined between the fifth to seventh gate electrodes GE5 to GE7 (see FIG. 3D). The second recess region RCR2 may be a recessed area formed on an upper portion of the device isolation layer ST.

The flat top surface PTS of the protrusion structure MS may be located at a first level LV1 (see FIG. 3B). The top surface of the device isolation layer ST below the gate electrode GE may be located at a second level LV2 (see FIG. 3C). The first level LV1 and the second level LV2 may be substantially the same as each other. A difference between the first level LV1 and the second level LV2 may be in a range of greater than about 0 nm and less than about 20 nm For example, the difference between the first level LV1 and the second level LV2 may be less than about 5 nm.

According to embodiments, no recess region may be formed on the device isolation layer ST between the second to fourth gate electrodes GE2 to GE4 that run across the first active region AR1. For example, the protrusion structure MS may be formed on an upper portion of the device isolation layer ST between neighboring first active regions AR1. For example, as shown in FIG. 3D, the device isolation layer ST and the protrusion structure MS may provide a substantially planar surface between the second to fourth gate electrodes GE2 to GE4 that run across the first active region AR1. Therefore, in a semiconductor device according to embodiments, the second to fourth gate electrodes GE2 to GE4 may be supported by the protrusion structure MS, thereby preventing the second to fourth gate electrodes GE2 to GE4 from collapsing, and the first source/drain patterns SD1 may be stably formed having a uniform size.

In an embodiment, the protrusion structure MS may be omitted on the device isolation structure ST between neighboring second active regions AR2 (see FIG. 3E). The second recess region RCR2 may be formed on the device isolation layer ST between neighboring second active regions AR2. The second recess region RCR2 may allow the device isolation layer ST to have a recessed top surface RCT. The recessed top surface RCT of the device isolation layer ST may be located at a third level LV3 (see FIG. 3E). The third level LV3 may be lower than the first level LV1 and the second level LV2.

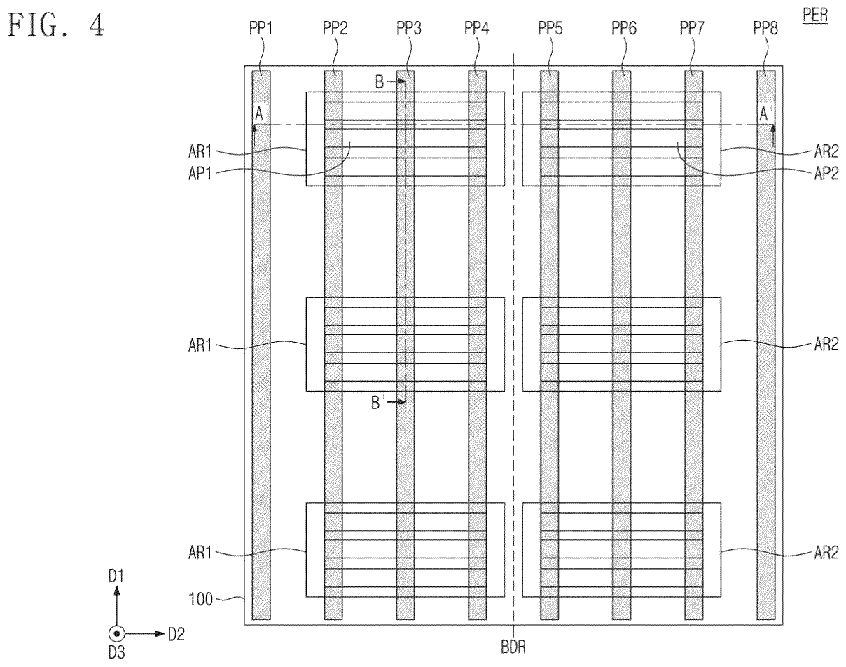

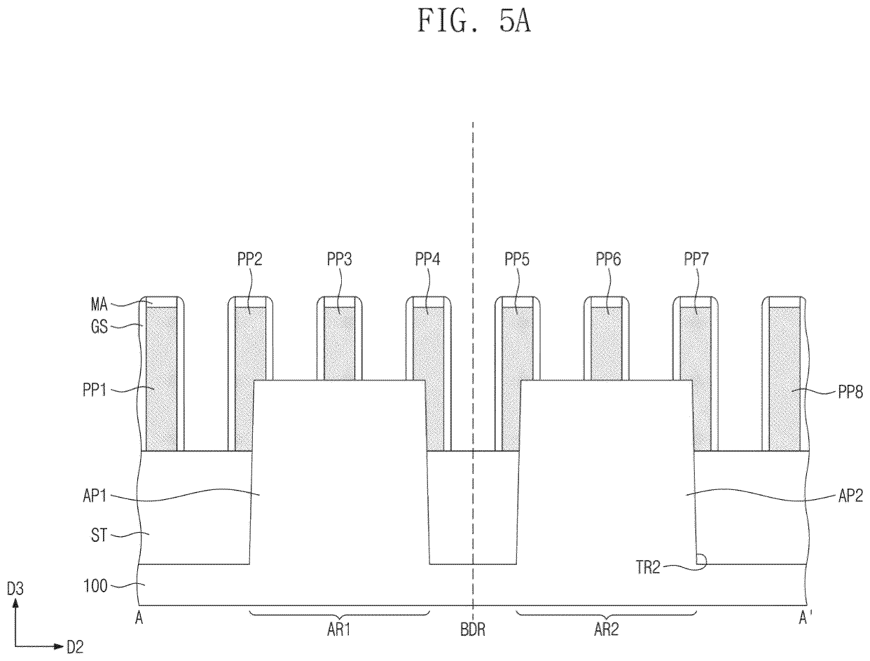

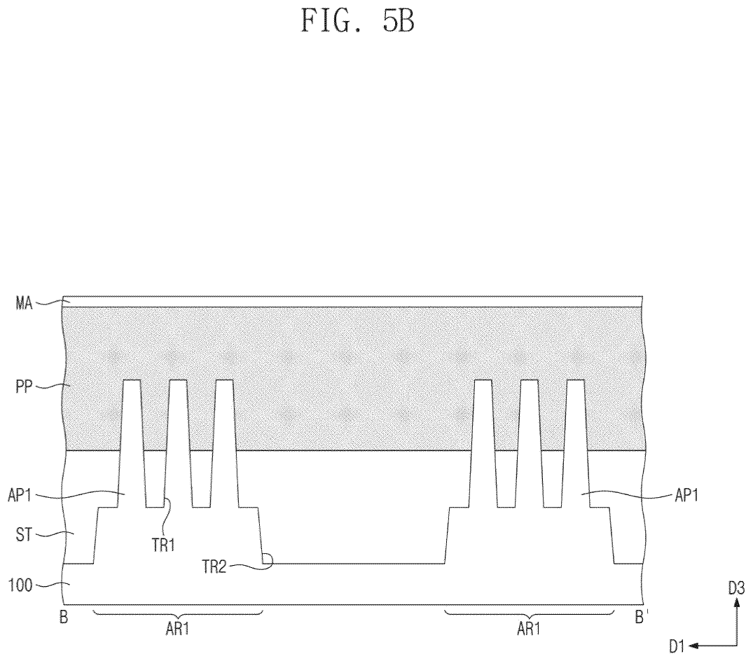

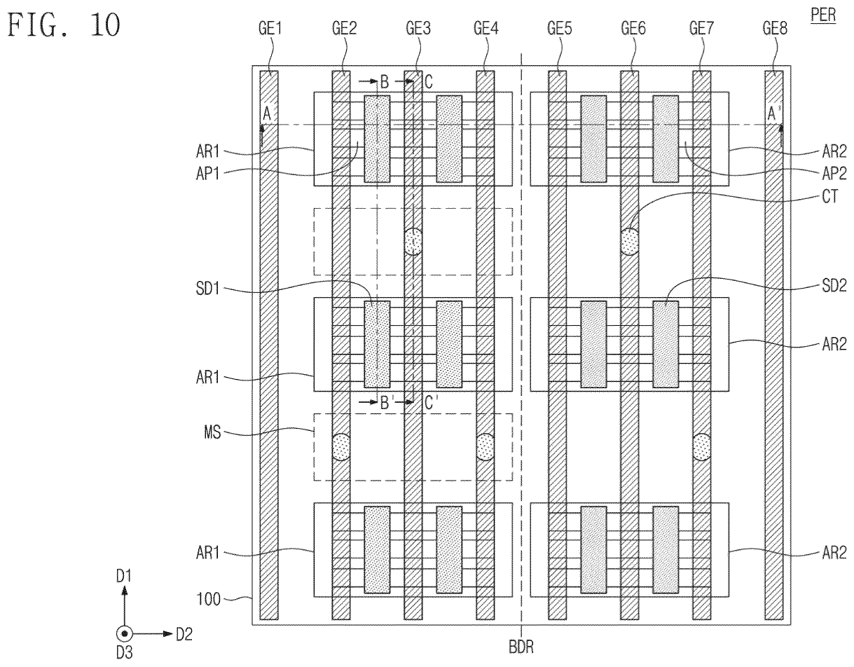

FIGS. 4, 6, 8, and 10 illustrate plan views showing a method of fabricating a semiconductor device according to some embodiments. FIGS. 5A, 7A, 9A, and 11A illustrate cross-sectional views taken along line A-A′ of FIGS. 4, 6, 8, and 10, respectively. FIGS. 5B, 7B, 9B, and 11B illustrate cross-sectional views taken along line B-B′ of FIGS. 4, 6, 8, and 10, respectively. FIG. 10C illustrates a cross-sectional view taken along line C-C′ of FIG. 10.

Referring to FIGS. 4, 5A, and 5B, a substrate 100 may be provided which includes a peripheral region PER. The substrate 100 may undergo a first patterning process to form a plurality of active patterns AP1 and AP2. The active patterns AP1 and AP2 may have linear shapes that extend in parallel in a second direction D2. During the first patterning process, a first trench TR1 may be formed between the active patterns AP1 and AP2. Each of the active patterns AP1 and AP2 may constitute an active fin.

The substrate 100 may undergo a second patterning process to form first active regions AR1 and second active regions AR2. During the second patterning process, a second trench TR2 may be formed which defines the first and second active regions AR1 and AR2. The second trench TR2 may be formed deeper than the first trench TR1. The second patterning process may remove the active patterns AP1 and AP2 on a region other than the first and second active regions AR1 and AR2.

First active patterns AP1 may remain on the first active region AR1. Second active patterns AP2 may remain on the second active region AR2. Each of the first active regions AR1 may be one of an NMOSFET region and a PMOSFET region, and each of the second active regions AR2 may be another of an NMOSFET region and a PMOSFET region. For example, each of the first active regions AR1 may be an NMOSFET region, and each of the second active regions AR2 may be a PMOSFET region.

A device isolation layer ST may be formed on the substrate 100. A device isolation layer ST may fill the first and second trenches TR1 and TR2. The device isolation layer ST may include a dielectric material, such as a silicon oxide layer. The device isolation layer ST may be recessed until an upper portion of each of the first and second active patterns AP1 and AP2 is exposed. Therefore, the first and second active patterns AP1 and AP2 may have upper portions that vertically protrude upwards from the device isolation layer ST.

A plurality of sacrificial patterns PP may be formed on the substrate 100. The sacrificial patterns PP may be formed to have a constant pitch along the second direction D2. The sacrificial patterns PP may be formed to have a linear shape that extends in a first direction D1.

The sacrificial patterns PP may include first to eighth sacrificial patterns PP1 to PP8. The second to fourth sacrificial patterns PP2 to PP4 may run across the first active regions AR1. The second to fourth sacrificial patterns PP2 to PP4 may run across the first active patterns AP1. The fifth to seventh sacrificial patterns PP5 to PP7 may run across the second active regions AR2. The fifth to seventh sacrificial patterns PP5 to PP7 may run across the second active patterns AP2.

For example, the formation of the sacrificial patterns PP may include forming a sacrificial layer on an entire surface of the substrate 100, forming mask patterns MA on the sacrificial layer, and using the mask patterns MA as an etching mask to pattern the sacrificial layer. The sacrificial layer may include polysilicon.

According to an embodiment, the patterning process for forming the sacrificial patterns PP may include a lithography process that uses an extreme ultraviolet (EUV) radiation. In this description, the EUV may mean an ultraviolet ray having a wavelength of about 4 nm to about 124 nm, narrowly of about 4 nm to about 20 nm, and more narrowly of about 13.5 nm. The EUV may denote light whose energy is in the range of about 6.21 eV to about 124 eV, for example, about 90 eV to about 95 eV.

The lithography process using the EUV may include exposure and development processes in which the EUV is irradiated onto a photoresist layer. For example, the photoresist layer may be an organic photoresist that contains an organic polymer such as polyhydroxystyrene. The organic photoresist may further include a photosensitive compound sensitive to the EUV. The organic photoresist may additionally include a material whose EUV absorption coefficient is high, for example, an organometallic material, an iodine-containing material, or a fluorine-containing material. For another example, the photoresist layer may be an inorganic photoresist that contains an inorganic material, such as tin oxide.

The photoresist layer may be formed to have a relatively small thickness. The photoresist layer exposed to the EUV may be developed to form photoresist patterns. When viewed in plan, the photoresist patterns may have a linear shape that extends in one direction, an island shape, a zigzag shape, a honeycomb shape, or a circular shape, but embodiments are not limited to a particular example.

The photoresist patterns may be used as an etching mask to pattern one or more mask layers that are stacked below the photoresist patterns, and thus the mask patterns MA may be formed. The mask patterns MA may be used as an etching mask to pattern a target layer or the sacrificial layer to form desired patterns or the sacrificial patterns PP on a wafer.

As a comparative example, a multi-patterning technique (MPT) requires the use of two or more photomasks to form fine-pitched patterns on a wafer. In contrast, when an EUV lithography process is performed according to an embodiment, only a single photomask may be used to form the sacrificial patterns PP.

For example, a value equal to or less than about 45 nm may be given as a minimum pitch between the sacrificial patterns PP formed by an EUV lithography process according to the present embodiment. Hence, the EUV lithography process used to form the sacrificial patterns PP may be sufficient to form very fine patterns without requiring the multi-patterning technique.

According to some embodiments, the EUV lithography process may be used to perform not only the patterning process for forming the sacrificial patterns PP, but also the patterning process for forming the first and second active patterns AP1 and AP2 discussed above, and no limitation is imposed on the EUV lithography process.

A pair of gate spacers GS may be formed on opposite sidewalls of each of the sacrificial patterns PP. The formation of the gate spacers GS may include conformally forming a gate spacer layer on the entire surface of the substrate 100 and anisotropically etching the gate spacer layer. The gate spacer layer may include at least one selected from SiCN, SiCON, and SiN.

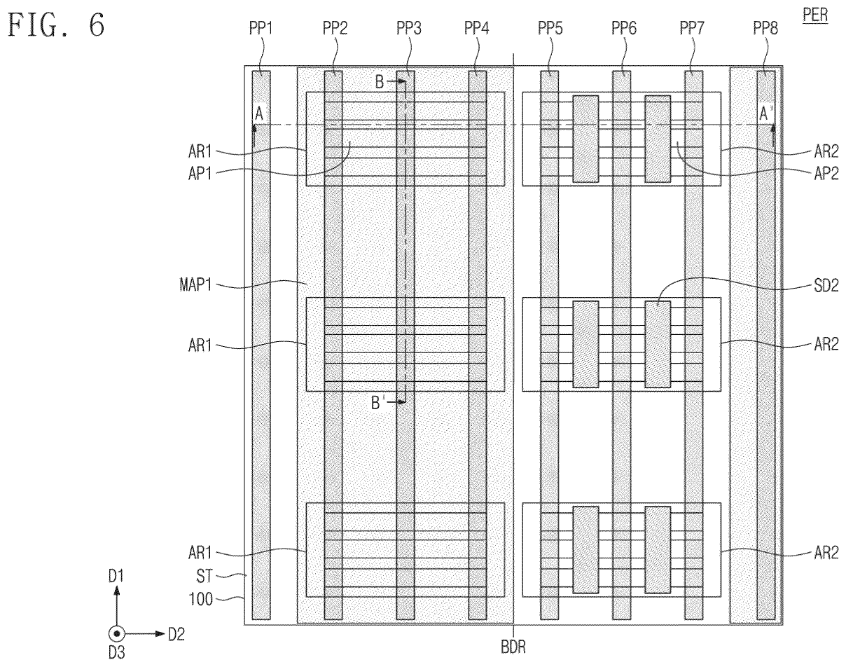

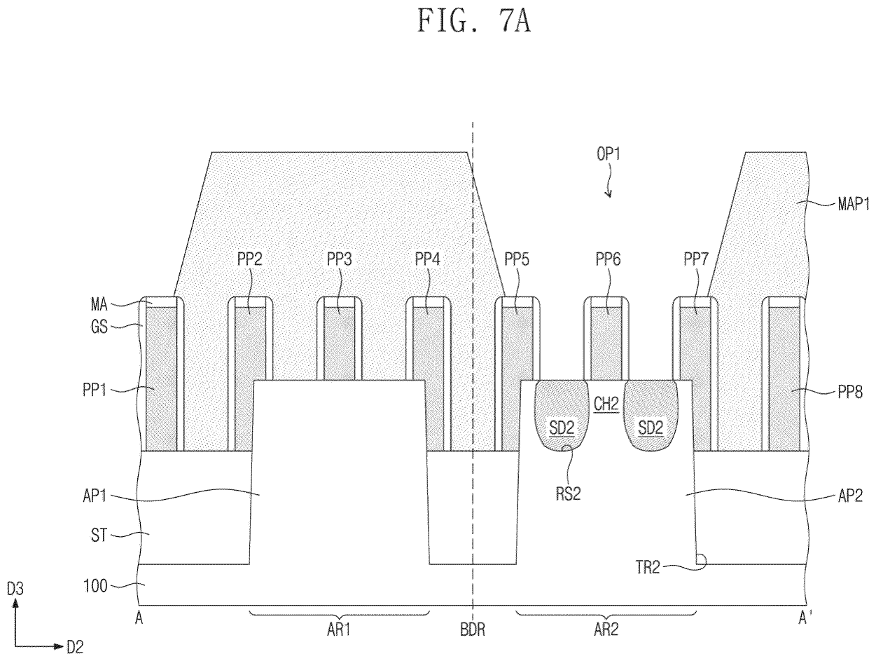

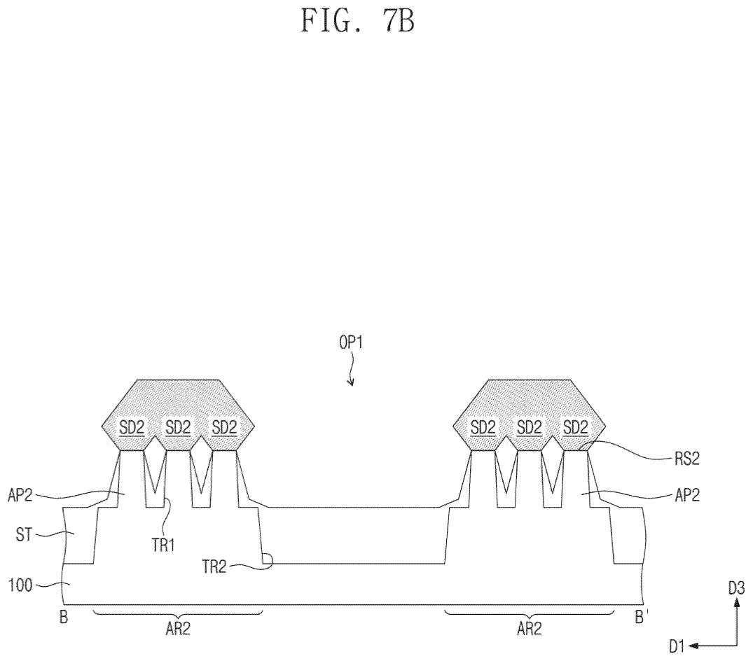

Referring to FIGS. 6, 7A, and 7B, a first hardmask layer MAP1 may be formed on the substrate 100. The first hardmask layer MAP1 may have a first opening OP1 that exposes the second active regions AR2. The first opening OP1 may continuously extend in the first direction D1. The first opening OP1 may expose all of the second active regions AR2 arranged along the first direction D1.

The first hardmask layer MAP1, the mask patterns MA, and the gate spacers GS may be used as an etching mask to etch an upper portion of the second active patterns AP2 to form second recesses RS2. For example, the second recess RS2 may be formed on the second active pattern AP2 between the fifth and sixth sacrificial patterns PP5 and PP6. The second recess RS2 may be formed on the second active pattern AP2 between the sixth and seventh sacrificial patterns PP6 and PP7. During the etching of the upper portion of the second active pattern AP2, the device isolation layer ST between the second active patterns AP2 may be recessed (see FIG. 7B).

A second source/drain pattern SD2 may be formed by performing a first selective epitaxial growth process in which an inner wall of the second recess RS2 of the second active pattern AP2 is used as a seed layer. A second channel pattern CH2 may be defined on the second active pattern AP2 between a pair of second source/drain patterns SD2. For example, the first selective epitaxial growth process may include a chemical vapor deposition (CVD) process or a molecular beam epitaxy (MBE) process. The second source/drain patterns SD2 may include a semiconductor element (e.g., SiGe) whose lattice constant is greater than that of a semiconductor element of the substrate 100. Each of the second source/drain patterns SD2 may be formed of a plurality of stacked semiconductor layers.

For example, impurities may be in-situ implanted during the first selective epitaxial growth process for forming the second source/drain patterns SD2. For another example, impurities may be implanted into the second source/drain patterns SD2 after the formation thereof. The second source/drain patterns SD2 may be doped have a first conductivity type (e.g., p-type).

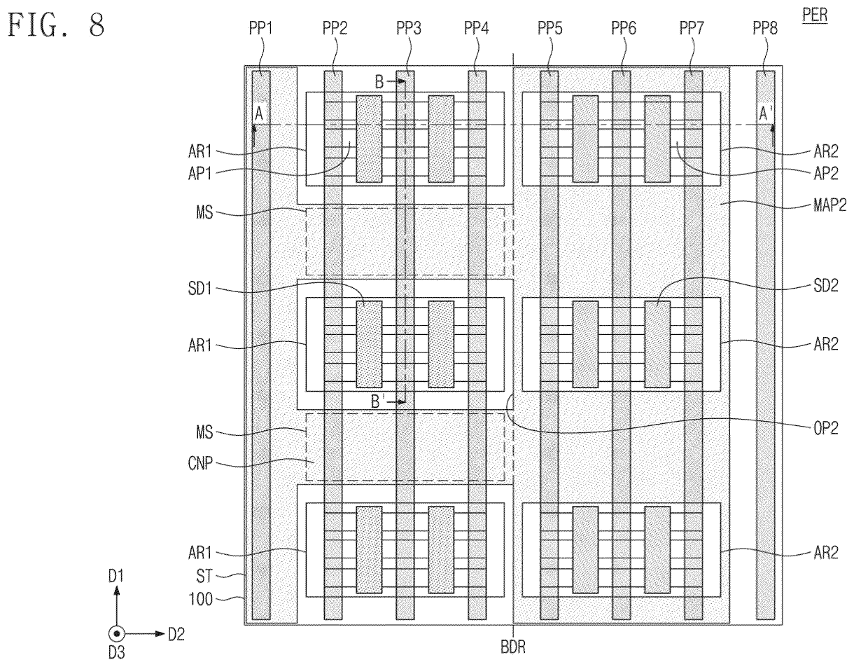

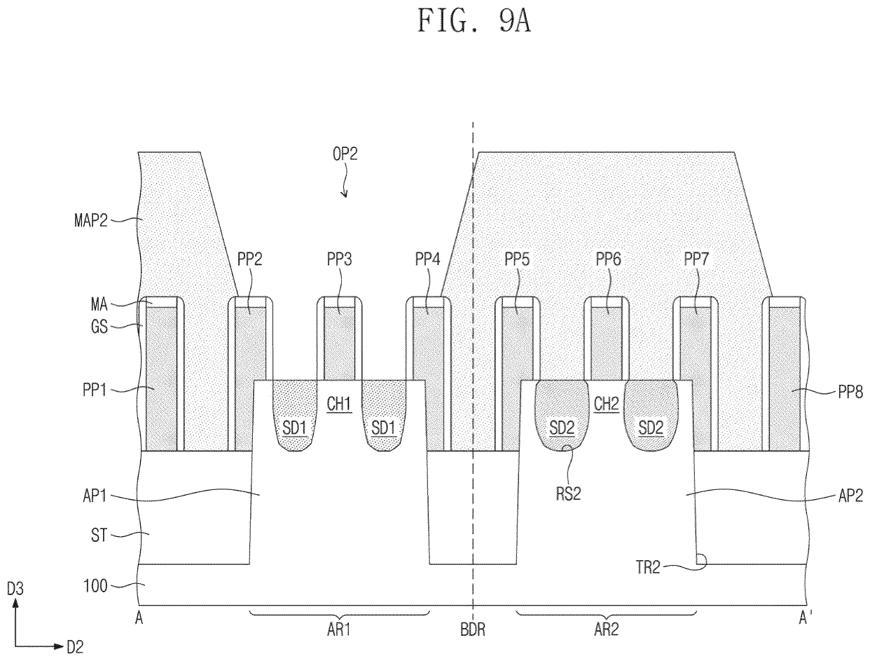

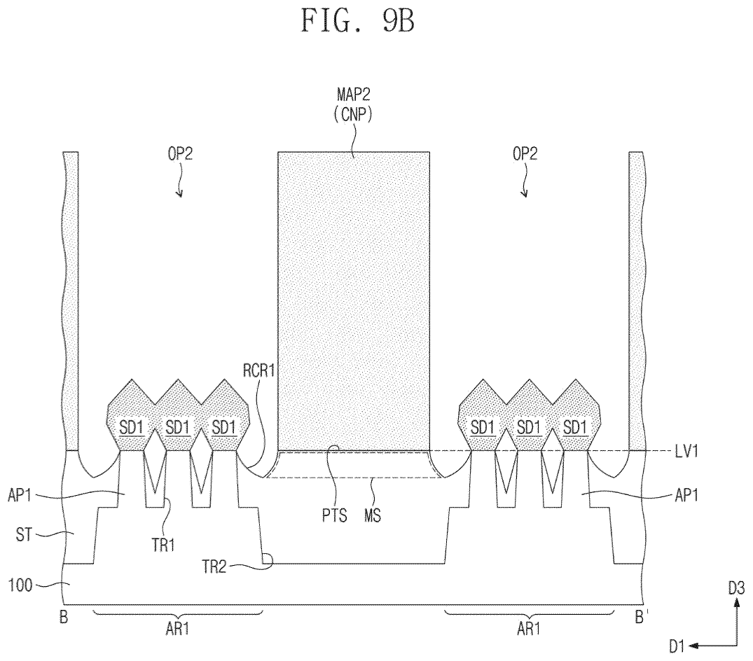

Referring to FIGS. 8, 9A, and 9B, the first hardmask layer MAP1 may be selectively removed. A second hardmask layer MAP2 may be formed on the substrate 100. The second hardmask layer MAP2 may have a second opening OP2 that exposes the first active regions AR1. The second hardmask layer MAP2 may include a support pattern CNP that overlaps a region between neighbor first active regions AR1. The support pattern CNP may have a bar shape that extends in the second direction D2. The support patterns CNP may divide the second opening OP2 into a plurality of island-shaped second openings OP2. The second opening OP2 may expose the first active region AR1.

The second hardmask layer MAP2, the mask patterns MA, and the gate spacers GS may be used as an etching mask to etch an upper portion of the first active pattern AP1 to form first recesses RS1. For example, the first recess RS1 may be formed on the first active pattern AP1 between the second and third sacrificial patterns PP2 and PP3. The first recess RS1 may be formed on the first active pattern AP1 between the third and fourth sacrificial patterns PP3 and PP4.

During the etching of the upper portion of the first active pattern AP1, the device isolation layer ST between the first active regions AR1 may be protected by the support pattern CNP of the second hardmask layer MAP2 (see FIG. 9B). Therefore, the device isolation layer ST between the first active regions AR1 may not be recessed, but may remain to form a protrusion structure MS. When viewed in plan, the protrusion structure MS may overlap the support pattern CNP.

The second hardmask layer MAP2 may allow the protrusion structure MS to have a flat top surface PTS. The flat top surface PTS of the protrusion structure MS may be located at a first level LV1. The first level LV1 may be substantially the same as a level of the top surface of the device isolation layer ST.

A first source/drain pattern SD1 may be formed by performing a second selective epitaxial growth process in which an inner wall of the first recess RS1 of the first active pattern AP1 is used as a seed layer. A first channel pattern CH1 may be defined on the first active pattern AP1 between a pair of first source/drain patterns SD1. For example, the first source/drain patterns SD1 may include the same semiconductor element (e.g., Si) as that of the substrate 100. The first source/drain patterns SD1 may be doped to have a first conductivity type (e.g., n-type).

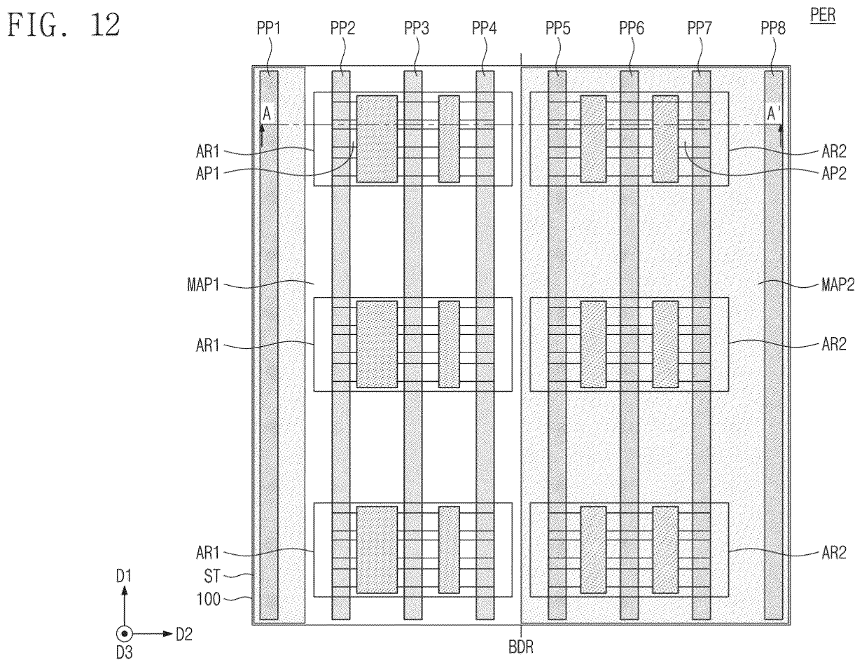

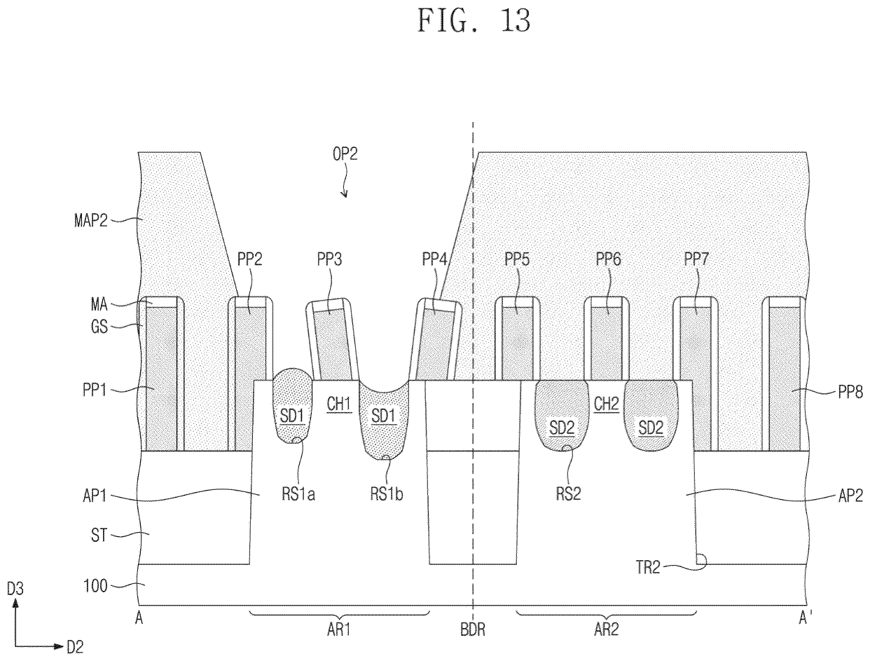

FIG. 12 illustrates a plan view showing a method of fabricating a semiconductor device according to a comparative example. FIG. 13 illustrates a cross-sectional view taken along line A-A′ of FIG. 12. Referring to FIGS. 12 and 13, the support pattern CNP of the second hardmask layer MAP2 may be omitted. The second opening OP2 of the second hardmask layer MAP2 may continuously extend in the first direction D1. The second opening OP2 may expose all of the first active regions AR1 arranged along the first direction D1.

At least one sacrificial pattern PP exposed by the second hardmask layer MAP2 may collapse (or lean). In an embodiment, the fourth sacrificial pattern PP4 adjacent to an N/P boundary BDR may be most susceptible to collapse. For example, contraction of the second hardmask layer MAP2 may cause collapse of the fourth sacrificial pattern PP4 positioned on a boundary of the second opening OP2 or on the N/P boundary BDR. In addition, because the third sacrificial pattern PP3 positioned on a center of the second opening OP2 has a high-aspect ratio, and because no support structure is present to physically support the third sacrificial pattern PP3, the third sacrificial pattern PP3 may also collapse (or lean).

As shown in FIG. 13, the third and fourth sacrificial patterns PP3 and PP4 on the first active region AR1 may be tilted to form first recesses RS1a and RS1b having different depths from each other. The first source/drain patterns SD1 formed in the first recesses RS1a and RS1b having different depths may have different sizes from each other.

Referring back to FIGS. 8, 9A, and 9B, the second hardmask layer MAP2 according to an embodiment may use the support pattern CNP to physically support the second to fourth sacrificial patterns PP2 to PP4. Therefore, collapse of the sacrificial pattern PP shown in FIG. 13 may be prevented even in the case of contraction of the second hardmask layer MAP2.

According to the present embodiment, collapse of the second to fourth sacrificial patterns PP2 to PP4 may be prevented such that the first recesses RS1 may be formed to have the same depth. The first source/drain patterns SD1 having the same size may be formed in the first recesses RS1. As a result, as collapse of a gate electrode is avoided and source/drain patterns are uniformly formed, a device may have improved electrical properties and increased reliability.

The present embodiment shows by way of example that the support pattern CNP is formed on the second hardmask layer MAP2, but the support pattern CNP may be or may also be formed on the first hardmask layer MAP1. For example, the support pattern CNP may be formed between neighboring second active regions AR2 in FIG. 6. In this case, the protrusion structure MS of the device isolation layer ST may be or may also be formed between the second active regions AR2.

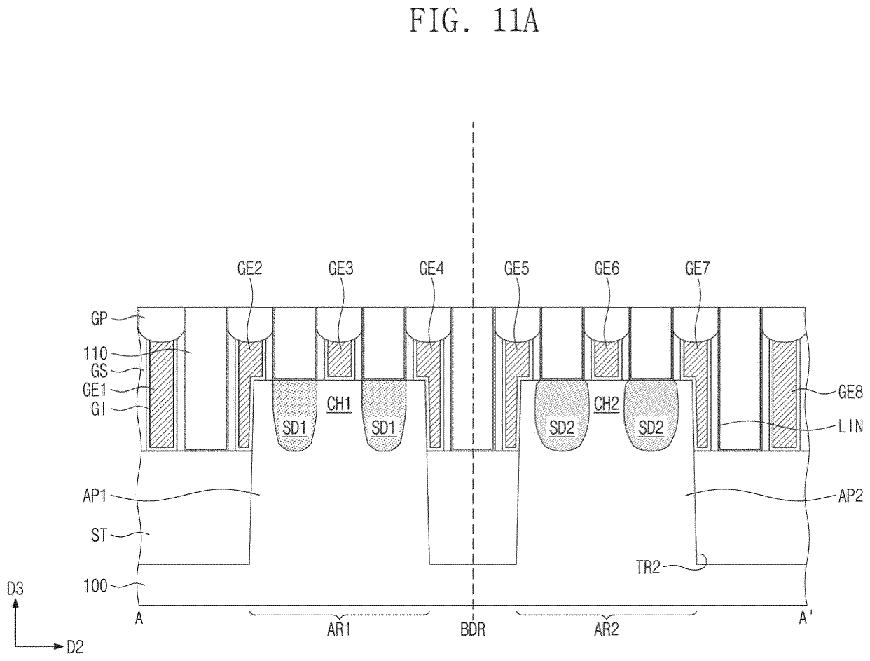

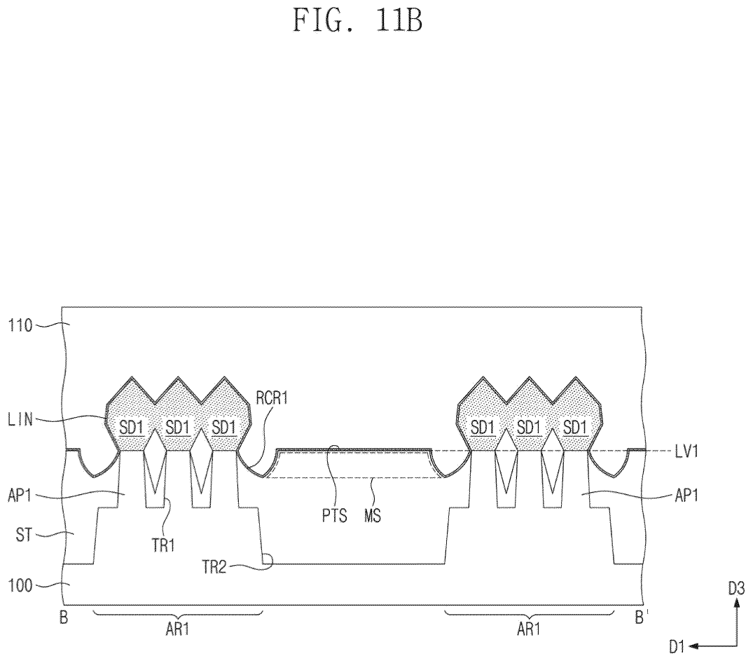

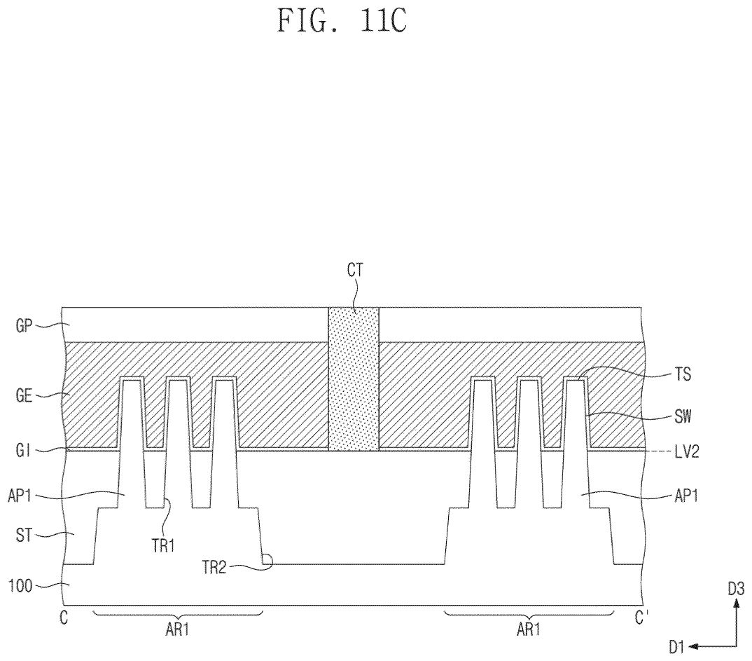

Referring to FIGS. 10, 11A, and 11B, a liner layer LIN may be formed to cover the device isolation layer ST, the first and second source/drain patterns SD1 and SD2, and the gate spacers GS. The liner layer LIN may be formed of one or more of a silicon nitride layer and a silicon oxynitride layer. A first interlayer dielectric layer 110 may be formed on the liner layer LIN. For example, the first interlayer dielectric layer 110 may include a silicon oxide layer.

The first interlayer dielectric layer 110 may be planarized until top surfaces of the sacrificial patterns PP are exposed. An etch-back or chemical mechanical polishing (CMP) process may be employed to planarize the first interlayer dielectric layer 110. The mask patterns MA may all be removed during the planarization process. As a result, the first interlayer dielectric layer 110 may have a top surface coplanar with those of the sacrificial patterns PP and those of the gate spacers GS.

A gate cutting pattern CT may be formed to penetrate the sacrificial pattern PP. For example, a photolithography process may be used to form a mask layer including an opening that defines a position where the gate cutting pattern CT will be formed. An etching process may be used to selectively remove the sacrificial pattern PP exposed by the opening. A region where the sacrificial pattern PP is removed may be filled with a dielectric material to form the gate cutting pattern CT. The sacrificial patterns PP covered with the mask layer may remain without being removed. Subsequently, the mask layer may be selectively removed.

The sacrificial patterns PP may be replaced with gate electrodes GE. For example, the exposed sacrificial patterns PP may be selectively removed. The removal of the sacrificial pattern PP may form an empty space. A gate dielectric layer GI and a gate electrode GE may be formed in the empty space.

An upper portion of the gate electrode GE may be recessed. During the recessing of the upper portion of the gate electrode GE, an upper portion of the gate spacer GS may also be recessed. A gate capping pattern GP may be formed on the recessed gate electrode GE. The gate capping pattern GP may be formed of one or more of SiON, SiCN, SiCON, and SiN.

Referring back to FIGS. 2 and 3A to 3E, a second interlayer dielectric layer 120 may be formed on the first interlayer dielectric layer 110. The second interlayer dielectric layer 120 may include a silicon oxide layer. Active contacts CT may be formed to penetrate the first and second interlayer dielectric layers 110 and 120 and to have electrical connection with the first and second source/drain patterns SD1 and SD2. Gate contacts GC may be formed to penetrate the second interlayer dielectric layer 120 and the gate capping pattern GP and to have electrical connections with corresponding gate electrodes GE.

A third interlayer dielectric layer 130 may be formed on the second interlayer dielectric layer 120. A first metal layer M1 may be formed in the third interlayer dielectric layer 130. The formation of the first metal layer M1 may include forming first wiring lines M1_I and first vias VI1.

A fourth interlayer dielectric layer 140 may be formed on the first metal layer M1. A second metal layer M2 may be formed in the fourth interlayer dielectric layer 140. The formation of the second metal layer M2 may include forming second wiring lines M2_I and second vias VI2. For example, the second via VI2 and the second wiring line M2_I may be formed together through a dual damascene process.

According to an embodiment, the formation of the first wiring lines M1_I and/or the second wiring lines M2_I may include performing an EUV lithography process. A detailed description of the EUV lithography process used in wiring processes, or a back-end-of-line (BEOL) process, may be substantially the same as that used for forming the sacrificial patterns PP. For example, about 45 nm or less may be given as a minimum pitch between the first wiring lines M1_I formed by the EUV lithography process according to the present embodiment.

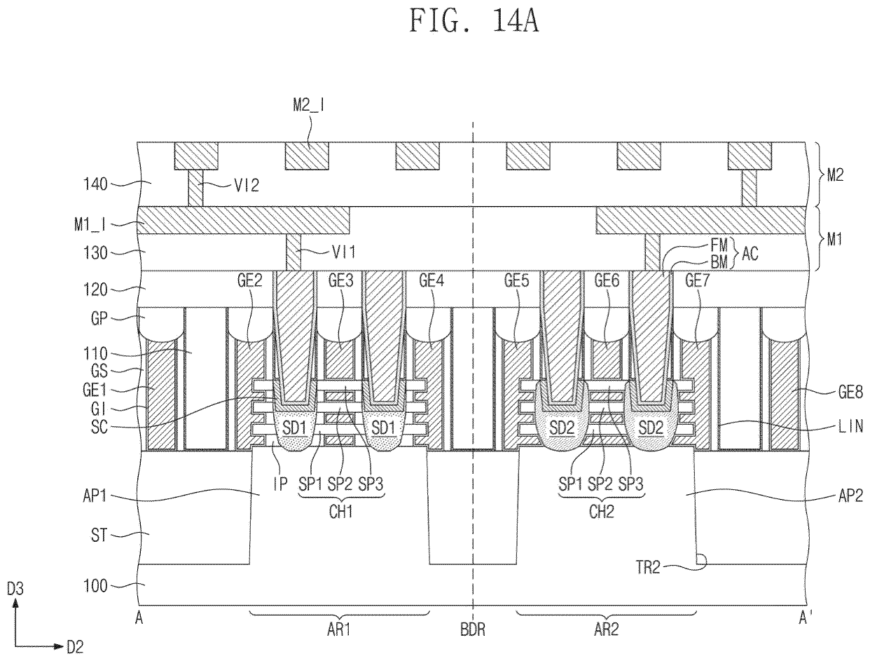

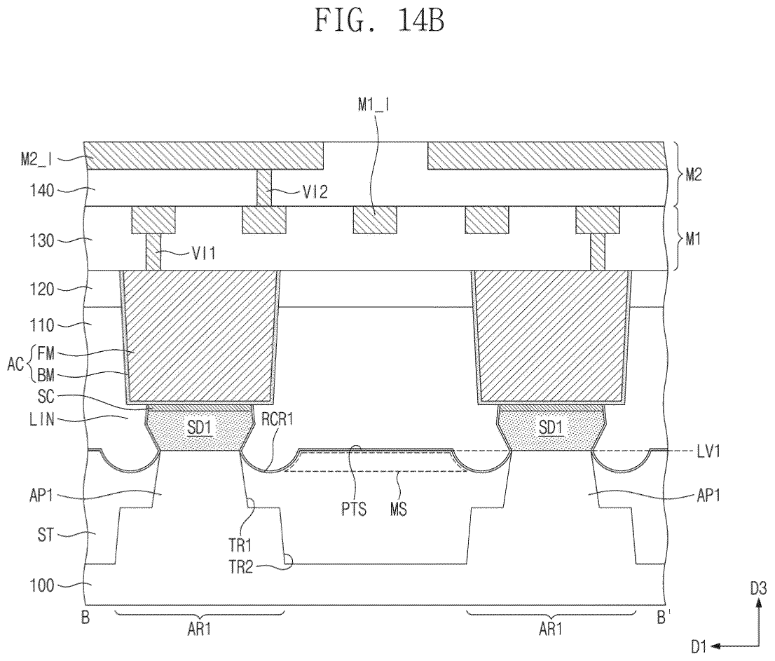

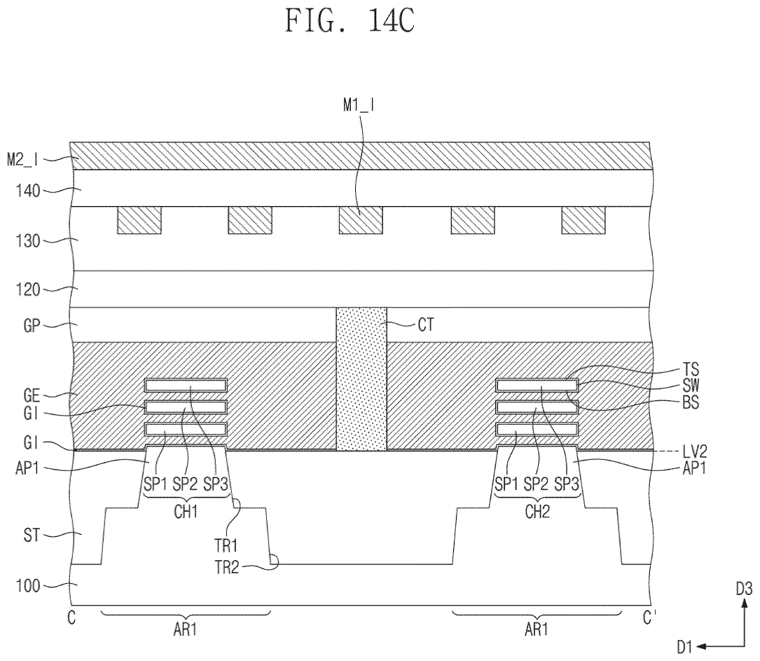

FIGS. 14A, 14B, and 14C illustrate cross-sectional views respectively taken along lines A-A′, B-B′, and C-C′ of FIG. 2, showing a semiconductor device according to some embodiments. Below, a detailed description of technical features repetitive to those discussed above with reference to FIGS. 2 and 3A to 3E will be omitted, and a difference from those discussed above with reference to FIGS. 1 and 3A to 3E will be discussed in detail.

Referring to FIGS. 2 and 14A to 14C, the device isolation layer ST may define a first active pattern AP1 and a second active pattern AP2 on an upper portion of the substrate 100. The first active pattern AP1 may be provided on a first active region AR1, and the second active pattern AP2 may be provided on a second active region AR2. The first active region AR1 may be one of an NMOSFET region and a PMOSFET region, and the second active region AR2 may be another of an NMOSFET region and a PMOSFET region.

First source/drain patterns SD1 may be provided on the first active pattern AP1, and a first channel pattern CH1 may be provided between the first source/drain patterns SD1. Second source/drain patterns SD2 may be provided on the second active pattern AP2, and a second channel pattern CH2 may be provided between the second source/drain patterns SD2.

Each of the first and second channel patterns CH1 and CH2 may include a first semiconductor pattern SP1, a second semiconductor pattern SP2, and a third semiconductor pattern SP3 that are sequentially stacked. The first, second, and third semiconductor patterns SP1, SP2, and SP3 may be spaced apart from each other in a vertical direction (or a third direction D3). The third semiconductor pattern SP3 may be an uppermost semiconductor pattern among the first, second, and third semiconductor patterns SP1, SP2, and SP3.

Each of the first, second, and third semiconductor patterns SP1, SP2, and SP3 may include silicon (Si), germanium (Ge), or silicon-germanium (SiGe). For example, each of the first, second, and third semiconductor patterns SP1, SP2, and SP3 may include crystalline silicon, for example, monocrystalline silicon. In an embodiment, the first, second, and third semiconductor patterns SP1, SP2, and SP3 may be stacked nano-sheets.

The first, second, and third semiconductor patterns SP1, SP2, and SP3 of the first channel pattern CH1 may connect a pair of neighboring first source/drain patterns SD1 to each other. The first, second, and third semiconductor patterns SP1, SP2, and SP3 of the second channel pattern CH2 may connect a pair of neighboring second source/drain patterns SD2 to each other.

Gate electrodes GE may be provided to extend in a first direction D1, while running across the first and second channel patterns CH1 and CH2. The gate electrode GE may vertically overlap the channel pattern CH1 or CH2. Referring back to FIG. 14C, the gate electrode GE may surround each of the first, second, and third semiconductor patterns SP1, SP2, and SP3. A transistor according to the present embodiment may be a three-dimensional field effect transistor (e.g. multi-bridge-channel FET (MBCFET) or gate-all-around FET (GAAFET)) in which the gate electrode GE three-dimensionally surrounds a channel or the nano-sheets SP1, SP2, and SP3.

For example, the gate electrode GE may surround a top surface TS, a bottom surface BS, and opposite sidewalls SW of each of the first, second, and third semiconductor patterns SP1, SP2, and SP3. A gate dielectric layer GI may be provided between the gate electrode GE and each of the first, second, and third semiconductor patterns SP1, SP2, and SP3. The gate dielectric layer GI may directly cover the top surface TS, the bottom surface BS, and the opposite sidewalls SW of each of the first, second, and third semiconductor patterns SP1, SP2, and SP3.

In an embodiment, on the first active region AR1, an inner spacer IP may be interposed between the gate dielectric layer GI and the first source/drain pattern SD1. The gate dielectric layer GI and the inner spacer IP may separate the gate electrode GE from the first source/drain pattern SD1. In contrast, on the second active region AR2, the inner spacer IP may be omitted.

According to some embodiments, the device isolation layer ST between neighboring first active regions AR1 may include a protrusion structure MS on an upper portion thereof. The protrusion structure MS may be provided between neighboring first source/drain patterns SD1 (see FIG. 14B). The protrusion structure MS may have a flat top surface PTS.

The flat top surface PTS of the protrusion structure MS may be located at a first level LV1 (see FIG. 14B). The device isolation layer ST below the gate electrode GE may have a top surface located at a second level LV2 (see FIG. 14C). The first level LV1 and the second level LV2 may be substantially the same as each other. A difference between the first level LV1 and the second level LV2 may be in a range of greater than about 0 nm and less than about 20 nm For example, the difference between the first level LV1 and the second level LV2 may be less than about 5 nm.

A first interlayer dielectric layer 110 and a second interlayer dielectric layer 120 may be provided on an entire surface of the substrate 100. Active contacts AC may be provided to penetrate the first and second interlayer dielectric layers 110 and 120 and to have connection with the first and second source/drain patterns SD1 and SD2. Gate contacts GC may be provided to penetrate the second interlayer dielectric layer 120 and the gate capping pattern GP and to have connection with corresponding gate electrodes GE. A detailed description of the active contacts AC and the gate contacts GC may be substantially the same as that discussed above with reference to FIGS. 2 and 3A to 3E.

A third interlayer dielectric layer 130 may be provided on the second interlayer dielectric layer 120. A fourth interlayer dielectric layer 140 may be provided on the third interlayer dielectric layer 130. A first metal layer M1 may be provided in the third interlayer dielectric layer 130. A second metal layer M2 may be provided in the fourth interlayer dielectric layer 140. A detailed description of the first metal layer M1 and the second metal layer M2 may be substantially the same as that discussed above with reference to FIGS. 2 and 3A to 3E.

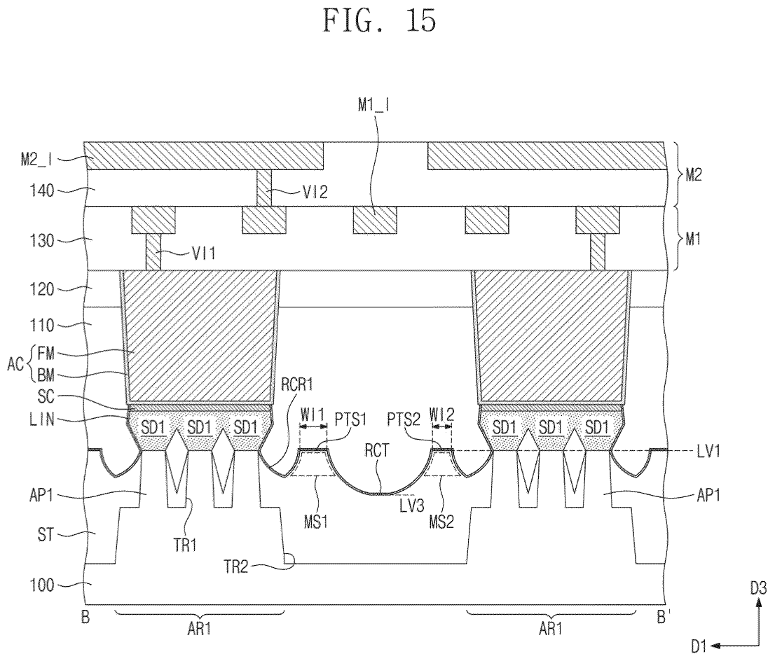

FIG. 15 illustrates a cross-sectional view taken along line B-B′ of FIG. 2, showing a semiconductor device according to some embodiments. Referring to FIG. 15, the device isolation layer ST between neighboring first active regions AR1 may include a pair of protrusion structures MS provided on an upper portion thereof. The pair of protrusion structures MS may include a first protrusion structure MS1 and a second protrusion structure MS2 that are spaced apart from each other in the first direction D1.

The first protrusion structure MS1 may have a first flat top surface PTS1, and the second protrusion structure MS2 may have a second flat top surface PTS2. The first flat top surface PTS1 and the second flat top surface PTS2 may be located at the same first level LV1.

The first protrusion structure MS1 and the second protrusion structure MS2 may be provided therebetween with a recessed top surface RCT of the device isolation layer ST. The recessed top surface RCT may have a lowermost portion located at a third level LV3. The third level LV3 may be lower than the first level LV1 and the second level LV2.

The first protrusion structure MS1 and the second protrusion structure MS2 may have different widths from each other. For example, the first flat top surface PTS1 of the first protrusion structure MS1 may have a first width WI1 in the first direction D1. The second flat top surface PTS2 of the second protrusion structure MS2 may have a second width WI2 in the first direction D1. The first width WI1 and the second width WI2 may be different from each other. For example, the first width WI1 may be greater than the second width WI2.

The first hardmask layer MAP1 discussed above in FIG. 6 may be formed to expose a region on which will be formed the support pattern CNP of the second hardmask layer MAP2 depicted in FIG. 8. Therefore, the recessed top surface RCT of FIG. 15 may be formed between neighboring first active regions AR1. Afterwards, the second hardmask layer MAP2 of FIG. 8 may be used to form a first recess region RCR1. As a result, a first protrusion structure MS1 and a second protrusion structure MS2 may be formed on the device isolation layer ST between neighboring first active regions AR1.

A semiconductor device according to embodiments may prevent collapse of a gate electrode adjacent to an N/P boundary. A support pattern on a protrusion structure may be used to prevent process defects due to the collapse of the gate electrode and to form source/drain patterns whose sizes are uniform. In conclusion, embodiments may improve reliability and electrical properties of the semiconductor device.

While aspects of embodiments have been particularly shown and described, it will be understood that various changes in form and details may be made therein without departing from the spirit and scope of the following claims.

What is claimed is:

1. A semiconductor device, comprising:
a substrate that comprises first active regions and second active regions, wherein the first active regions are arranged along a first direction, wherein the second active regions are arranged along the first direction, and wherein a boundary between the first active regions and the second active regions extends in the first direction;
a device isolation layer on the substrate in a trench between the first active regions and the second active regions;
a first channel pattern and a first source/drain pattern on each of the first active regions;
a second channel pattern and a second source/drain pattern on each of the second active regions;
a first gate electrode on the first channel pattern, wherein the first gate electrode extends in the first direction across the first active regions;
a second gate electrode on the second channel pattern, wherein the second gate electrode extends in the first direction across the second active regions; and
a plurality of active contacts on the first source/drain pattern on each of the first active regions and the second source/drain pattern on each of the second active regions,
wherein the device isolation layer comprises a protrusion structure between adjacent ones of the first active regions, and
wherein the protrusion structure is adjacent to the boundary.

2. The semiconductor device of claim 1, wherein, when viewed in plan, the protrusion structure has a bar shape that extends in a second direction intersecting the first direction.

3. The semiconductor device of claim 1, wherein the protrusion structure is a region of the device isolation layer which extends in a vertical direction, and
wherein the protrusion structure has a planar top surface.

4. The semiconductor device of claim 1, wherein the device isolation layer further comprises a recess region between the protrusion structure and the first source/drain pattern.

5. The semiconductor device of claim 1, wherein a top surface of the protrusion structure is at a first level,
wherein a top surface of the device isolation layer below the first gate electrode is at a second level, and
wherein a difference between the first level and the second level is in a range of greater than about 0 nm and less than about 20 nm.

6. The semiconductor device of claim 1, wherein each of the first active regions is one of an n-type metal-oxide-semiconductor field-effect transistor (NMOSFET) region and a p-type metal-oxide-semiconductor field-effect transistor (PMOSFET) region, and
wherein each of the second active regions is another of the NMOSFET region and the PMOSFET region.

7. The semiconductor device of claim 1, wherein a recessed top surface is formed in the device isolation layer between the second active regions that are adjacent to each other, and
wherein the recessed top surface is at a level lower than a level of a top surface of the protrusion structure.

8. The semiconductor device of claim 1, further comprising a liner layer on the device isolation layer, the first source/drain pattern on each of the first active regions and the second source/drain pattern on each of the second active regions,
wherein the liner layer directly covers the protrusion structure.

9. The semiconductor device of claim 1, wherein the first gate electrode comprises a pair of first gate electrodes adjacent to each other and on the device isolation layer,
wherein the second gate electrode comprises a pair of second gate electrodes adjacent to each other and on the device isolation layer,
wherein the protrusion structure is provided on the device isolation layer between the pair of first gate electrodes, and
wherein a recess region is provided on the device isolation layer between the pair of second gate electrodes.

10. The semiconductor device of claim 1, wherein the protrusion structure comprises a first protrusion structure and a second protrusion structure that are spaced apart from each other in the first direction, and
wherein a width in the first direction of the first protrusion structure is different from a width in the first direction of the second protrusion structure.

11. A semiconductor device, comprising:
a substrate that comprises a first active region and a second active region, wherein the first active region and the second active region are adjacent to each other along a first direction and have a common conductivity type;
a device isolation layer in a trench between the first active region and the second active region;
a first source/drain pattern on the first active region;
a second source/drain pattern on the second active region;
a liner layer on the device isolation layer and the first and second source/drain patterns;
an interlayer dielectric layer on the liner layer;
a first active contact that extends into the interlayer dielectric layer and is coupled to the first source/drain pattern; and
a second active contact that extends into the interlayer dielectric layer and is coupled to the second source/drain pattern,
wherein the device isolation layer comprises a protrusion structure that extends vertically between the first source/drain pattern and the second source/drain pattern, and
wherein the protrusion structure has a planar top surface.

12. The semiconductor device of claim 11, wherein, when viewed in plan, the protrusion structure has a bar shape that extends in a second direction intersecting the first direction.

13. The semiconductor device of claim 11, wherein the device isolation layer comprises:
a first recess region between the protrusion structure and the first source/drain pattern; and
a second recess region between the protrusion structure and the second source/drain pattern.

14. The semiconductor device of claim 11, wherein each of the first and second active regions is one of an n-type metal-oxide-semiconductor field-effect transistor (NMOSFET) region and a p-type metal-oxide-semiconductor field-effect transistor (PMOSFET) region.

15. The semiconductor device of claim 11, wherein the first source/drain pattern and the second source/drain pattern are n-type epitaxial patterns.

16. A semiconductor device, comprising:
a substrate that comprises first active regions and second active regions, wherein the first active regions are adjacent to each other along a first direction, and wherein the second active regions are adjacent to each other along the first direction;
a device isolation layer in a first trench between the first active regions and a second trench between the second active regions;
a first channel pattern and a first source/drain pattern on each of the first active regions;
a second channel pattern and a second source/drain pattern on each of the second active regions, wherein a conductivity type of the second source/drain pattern is different from a conductivity type of the first source/drain pattern;
a first gate electrode on the first channel pattern, wherein the first gate electrode extends in the first direction across the first active regions;
a first gate dielectric layer between the first gate electrode and the first channel pattern;
a second gate electrode on the second channel pattern, wherein the second gate electrode extends in the first direction across the second active regions;
a second gate dielectric layer between the second gate electrode and the second channel pattern;
a first active contact on the first source/drain pattern;
a second active contact on the second source/drain pattern;
a first gate contact on the first gate electrode;
a second gate contact on the second gate electrode; and
a first metal layer electrically connected to the first gate contact, the second gate contact, the first active contact and the second active contact,
wherein the device isolation layer between adjacent ones of the first active regions comprises a protrusion structure, and
wherein a recessed top surface is formed in the device isolation layer between adjacent ones of the second active regions.

17. The semiconductor device of claim 16, further comprising a liner layer on the device isolation layer, the first source/drain pattern on each of the first active regions and the second source/drain pattern on each of the second active regions,
wherein the liner layer directly covers the protrusion structure and the recessed top surface.

18. The semiconductor device of claim 16, wherein a top surface of the protrusion structure is at a first level,
wherein the recessed top surface is at a second level, and
wherein the second level is lower than the first level.

19. The semiconductor device of claim 18, wherein a top surface of the device isolation layer below the first gate electrode is at a third level, and
wherein a difference between the first level and the third level is in a range of greater than about 0 nm and less than about 20 nm.

20. The semiconductor device of claim 16, wherein each of the first active regions is one of an n-type metal-oxide-semiconductor field-effect transistor (NMOSFET) region and a p-type metal-oxide-semiconductor field-effect transistor (PMOSFET) region, and
wherein each of the second active regions is another of the NMOSFET region and the PMOSFET region.
